(19) United States
(12) Patent Application Publication
(10) Pub. No.: US 2007/0212866 A1
(43) Pub. Date: Sep. 13, 2007

(54) Method of manufacturing semiconductor device

(76) Inventor: Daisuke Inomata, Tokyo (JP)

Correspondence Address: VOLENTINE & WHITT PLLC, ONE FREEDOM SQUARE, 11951 FREEDOM DRIVE SUITE 1260, RESTON, VA, 20190, US

(21) Appl. No.: 11/657,641

(22) Filed: Jan. 25, 2007

(30) Foreign Application Priority Data
Mar. 8, 2006 (JP) 2006-063073

(51) Int. Cl. H01L 21/44

(52) U.S. Cl. 438/597

(57) ABSTRACT

In the present invention, a connection plug region where a connection plug is disposed has a long shape comprising a first length direction and a first width direction, an open region that is exposed by an open portion disposed in an insulation layer on the connection plug has a long shape comprising a second length direction and a second width direction, and during etching when disposing the open portion, the first length direction of the connection plug region and the second length direction of the open region are disposed such that they intersect so as to form a predetermined angle. Thus, it becomes possible to improve the reliability of the electrical connection between the connection plug and the conductive film deposited inside the open portion.

### CROSS-REFERENCE TO RELATED APPLICATION

This application claims priority under 35 USC 119 from Japanese Patent Application No. 2006-063073, the disclosure of which is incorporated by reference herein.

### BACKGROUND OF THE INVENTION

1. Field of the Invention

The present invention relates to a method of manufacturing a semiconductor device, and in particular to a method of manufacturing a semiconductor device comprising a multilayer wiring layer formed on a semiconductor substrate.

2. Description of the Related Art

Conventionally, with respect to a multilayer wiring layer formed on a semiconductor substrate, the following configuration using a conductive connection plug has been known as a method of electrically connecting the wiring layers together or the wiring layers and a predetermined region of the semiconductor substrate surface.

First, a first insulation layer is formed on a semiconductor substrate surface or a foundation layer such as an underlying wiring layer, and a conductive connection plug that penetrates the first insulation layer and is electrically connected to the foundation layer is formed on the first insulation layer. Moreover, a second insulation layer that covers the connection plug is formed on the first insulation layer. Next, an open portion that includes a connection plug region and has a shape that is larger than that of a connection plug region where the connection plug is disposed is disposed in the second insulation layer, and the surface of the connection plug is exposed by the open portion. Moreover, a conductive film is deposited on the second insulation layer and inside the open portion disposed in the second insulation layer, the conductive film is patterned, and a wiring layer electrically connected to the connection plug is formed on the second insulation layer.

This configuration is disclosed in FIG. 4, and in the paragraphs describing FIG. 4, of Japanese Patent Application Publication (JP-A) No. 7-99194, for example.

In JP-A No. 7-99194, a conductor plug 30 that penetrates a first interlayer insulation layer 22 formed on a lower conductive layer 20 and is electrically connected to the lower conductive layer 20 is formed on the first interlayer insulation layer 22, and a second interlayer insulation layer 34 is formed on the first interlayer insulation layer 22 so as to cover the conductor plug 30. Next, an auxiliary contact hole 36 that includes a semiconductor plug region and has a shape that is larger than that of a semiconductor plug region where the conductor plug 30 is formed is disposed in the second insulation layer 34, and the surface of the conductor plug 30 is exposed at the bottom of the auxiliary contact hole 36. Moreover, a second wiring forming layer 54 is deposited on the second interlayer insulation layer 34 and inside the auxiliary contact hole 36, the second wiring forming layer 54 is patterned, and a second wiring layer 38 is formed.

According to this conventional configuration, it becomes possible to electrically connect, using just the connection plug having the thickness of the first insulation layer, the foundation layer and the wiring layer formed on the foundation layer via laminated insulation layers such as the first and second insulation layers, so that it becomes possible to realize electrical connection between the foundation layer and the wiring layer without having to make the steps complicated.

That is, as a configuration for electrically connecting the foundation layer and the wiring layer formed on the foundation layer via the laminated insulation layers, there is the method of disposing a connection plug that penetrates all of the laminated insulation layers and electrically connecting the connection plug to the foundation layer and the wiring layer, but in this method, it is necessary to form a hole for the connection plug at the same depth as the thickness of the laminated insulation layers, so there has been the potential for the aspect ratio of the hole to become large so that the material for the connection plug cannot be easily implanted inside the hole, and there has been the potential for the steps to become complicated. Further, in a method of disposing a connection plug in each insulation layer configuring the laminated insulation layers and electrically connecting the connection plugs to each other, it becomes necessary to perform the step of implanting the connection plug several times, and there has been the potential for the amount of time for the step to significantly increase. For these reasons, with respect to a multilayer wiring layer formed on a semiconductor substrate, sometimes the above conventional configuration has been applied as a method of electrically connecting the wiring layers together or the wiring layers and a predetermined region of the semiconductor substrate.

However, in the above conventional configuration, the open portion disposed in the second insulation layer has a shape that is larger than that of the connection plug region and includes a connection plug region, so when the open portion is disposed by working the second insulation layer by dry etching, for example, there has been the potential for the region surrounding the connection plug in the underlying first insulation layer to be over-etched such that the upper portion of the connection plug protrudes from the first insulation layer.

In this case, there has been the potential for the conductive film that is to be deposited inside the open portion to not be preferably deposited on the side surface of the protruding connection plug, and there has been the potential for the conductive film to not be continuously formed on the inner surface of the open portion (this state will be called “open defect” below). Thus, there has been the potential for the reliability of the electrical connection between the connection plug and the conductive film configuring the wiring layer to be reduced. Particularly when the conductive film has been deposited by sputtering or the like, step coatability in sputtering is not good in comparison to chemical vapor deposition (CVD), so there has been the potential for the deposition on the side surface of the protruding connection plug to become more difficult and for the reduction in the reliability of the electrical connection to become more remarkable.

### SUMMARY OF THE INVENTION

In order to address these problems, a semiconductor device manufacturing method of the present invention includes: forming, in a first insulation layer formed on a foundation layer, a conductive connection plug whose surface is exposed from the first insulation layer and which penetrates the first insulation layer and is electrically connected to the foundation layer; forming a second insulation layer on the surface of the connection plug and on the first insulation layer; etching to dispose in the second insulation layer an open portion that exposes the connection plug and the first insulation layer; depositing a conductive film on the second insulation layer and inside the open portion; and patterning the deposited conductive film to form on the second insulation layer a wiring layer electrically connected to the connection plug, wherein a connection plug region that is the surface of the connection plug has a long shape comprising a first length direction and a first width direction, an open region that is exposed by the open portion has a long shape comprising a second length direction and a second width direction, and during the etching, the open portion is positioned such that the first length direction of the connection plug region and the second length direction of the open region intersect so as to form a predetermined angle.

According to this configuration, it becomes possible to improve the reliability of the electrical connection between the connection plug and the conductive film deposited inside the open portion disposed in the second insulation layer on the connection plug.

### BRIEF DESCRIPTION OF THE DRAWINGS

Preferred exemplary embodiments of the present invention will be described in detail based on the following figures, wherein:

FIG. 1 is a cross-sectional diagram showing a semiconductor device manufacturing method pertaining to a first exemplary embodiment of the invention;

FIG. 2 is a cross-sectional diagram showing the semiconductor device manufacturing method pertaining to the first exemplary embodiment of the invention;

FIG. 3 is a cross-sectional diagram showing the semiconductor device manufacturing method pertaining to the first exemplary embodiment of the invention;

FIG. 4 is a cross-sectional diagram showing the semiconductor device manufacturing method pertaining to the first exemplary embodiment of the invention;

FIG. 5 is a cross-sectional diagram showing the semiconductor device manufacturing method pertaining to the first exemplary embodiment of the invention;

FIG. 6 is a cross-sectional diagram showing the semiconductor device manufacturing method pertaining to the first exemplary embodiment of the invention;

FIG. 7 is a cross-sectional diagram showing the semiconductor device manufacturing method pertaining to the first exemplary embodiment of the invention;

FIG. 8 is a plan diagram describing the semiconductor device manufacturing method pertaining to the first exemplary embodiment of the invention;

FIG. 9 is a plan diagram describing the semiconductor device manufacturing method pertaining to the first exemplary embodiment of the invention;

FIG. 10 is a plan diagram describing the semiconductor device manufacturing method pertaining to the first exemplary embodiment of the invention;

FIG. 11 is a plan diagram describing the semiconductor device manufacturing method pertaining to the first exemplary embodiment of the invention;

FIG. 12 is a plan diagram describing the semiconductor device manufacturing method pertaining to the first exemplary embodiment of the invention;

FIG. 13 is a plan diagram describing the semiconductor device manufacturing method pertaining to the first exemplary embodiment of the invention;

FIG. 14 is a plan diagram describing the semiconductor device manufacturing method pertaining to the first exemplary embodiment of the invention;

FIG. 15 is a plan diagram describing the semiconductor device manufacturing method pertaining to the first exemplary embodiment of the invention;

FIG. 16 is a plan diagram describing the semiconductor device manufacturing method pertaining to the first exemplary embodiment of the invention;

FIG. 17 is a cross-sectional diagram showing a semiconductor device manufacturing method pertaining to a second exemplary embodiment of the invention;

FIG. 18 is a cross-sectional diagram showing the semiconductor device manufacturing method pertaining to the second exemplary embodiment of the invention;

FIG. 19 is a cross-sectional diagram showing the semiconductor device manufacturing method pertaining to the second exemplary embodiment of the invention;

FIG. 20 is a cross-sectional diagram showing the semiconductor device manufacturing method pertaining to the second exemplary embodiment of the invention;

FIG. 21 is a cross-sectional diagram showing the semiconductor device manufacturing method pertaining to the second exemplary embodiment of the invention;

FIG. 22 is a cross-sectional diagram showing the semiconductor device manufacturing method pertaining to the second exemplary embodiment of the invention;

FIG. 23 is a cross-sectional diagram showing the semiconductor device manufacturing method pertaining to the second exemplary embodiment of the invention;

FIG. 24 is a cross-sectional diagram showing the semiconductor device manufacturing method pertaining to the second exemplary embodiment of the invention;

FIG. 25 is a plan diagram describing the semiconductor device manufacturing method pertaining to the second exemplary embodiment of the invention; and

FIG. 26 is a cross-sectional diagram describing an open defect in the description of the first exemplary embodiment of the invention.

### DETAILED DESCRIPTION OF THE INVENTION

Exemplary embodiments of the present invention will be described in detail below with reference to the drawings. It will be noted that the same reference numerals will be given to configurations that are the same throughout all of the drawings.

### First Exemplary Embodiment

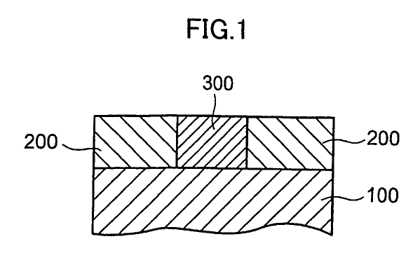

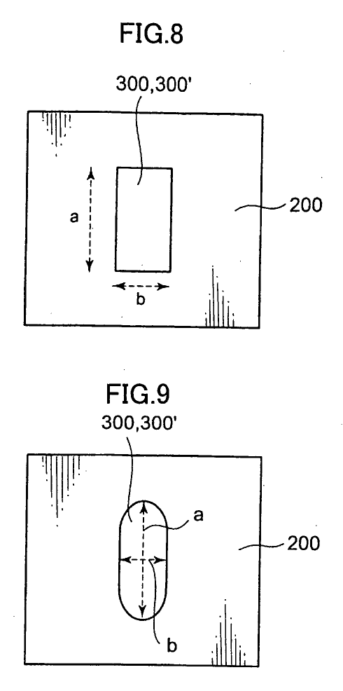

FIGS. 1 to 16 are step diagrams describing, in step order, a semiconductor device manufacturing method pertaining to a first exemplary embodiment of the invention. Here, FIGS. 1 to 7 are cross-sectional diagrams, and FIGS. 8 to 16 are plan diagrams.

In the semiconductor device manufacturing method pertaining to the first exemplary embodiment of the invention, first, as shown in FIG. 1, a conductive connection plug 300 is formed in a first insulation layer 200 formed on a foundation layer 100. The surface of the conductive connection plug 300 is exposed from the first insulation layer, and the conductive connection plug 300 penetrates the first insulation layer 200 and is electrically connected to the foundation layer 100.

The foundation layer 100 is an impurity diffusion layer formed on the surface portion of a semiconductor substrate whose material is silicon (Si), for example, or is an underlying wiring layer that configures part of a multilayer wiring layer formed on a semiconductor substrate.

In the present embodiment, the first insulation layer 200 is configured by a silicon dioxide film (SiO₂) and is formed by chemical vapor deposition (CVD), for example.

The connection plug 300 is formed by forming a contact hole in the first insulation layer 200 by etching using photolithography, then sequentially depositing, by sputtering or CVD, a metal layer whose material is titanium (Ti), titanium nitride (TiN), and tungsten (W) on the first insulation layer 200 in which the contact hole has been formed, and then polishing the deposited metal layer by chemical mechanical polishing (CMP).

In the present embodiment, as shown in the plan diagrams of FIG. 8 and FIG. 9, the surface of the connection plug 300 exposed from the first insulation layer 200—that is, a connection plug region 300′ where the connection plug 300 is to be disposed—has a long shape comprising a first long direction a and a first width direction b. For example, the shape of the connection plug region 300′ may be a rectangular shape as shown in FIG. 8 or an oval shape as shown in FIG. 9. In the case of a rectangular shape, the long edge direction corresponds to the first length direction a and the short edge direction corresponds to the first width direction b. In the case of an oval shape, the long axis direction corresponds to the first length direction a and the short axis direction corresponds to the first width direction b.

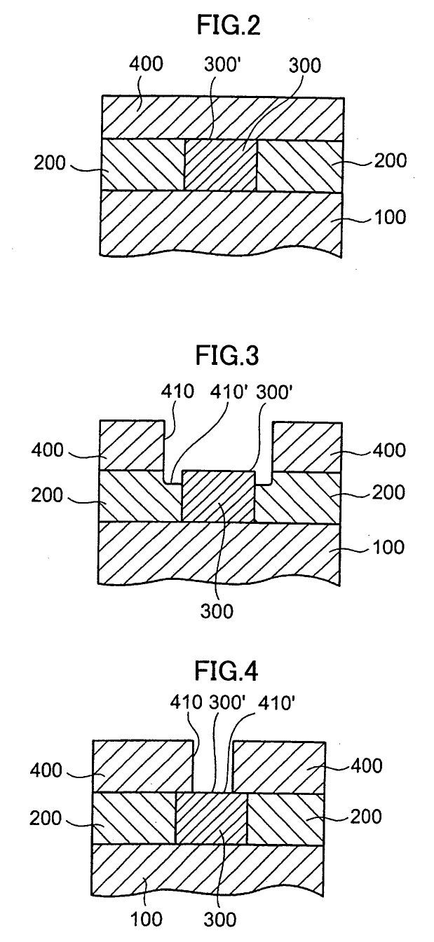

Next, as shown in FIG. 2, a second insulation layer 400 is formed on the first insulation layer 200 and on the connection plug region 300′.

The second insulation layer 200 is configured by a silicon dioxide film (SiO₂) and is formed by CVD, for example.

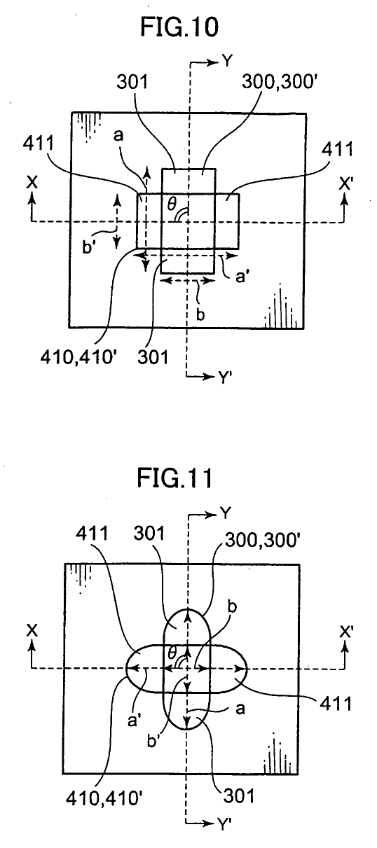

Next, as shown in FIG. 3, FIG. 4, FIG. 10, and FIG. 11, an open portion 410 that exposes part of the connection plug region 300′ and part of the first insulation layer 200 is disposed in the second insulation layer 400 by etching.

FIG. 3 is a cross-sectional diagram corresponding to dotted line X-X′ in the plan diagram shown in FIG. 10 and FIG. 11, and FIG. 4 is a cross-sectional diagram corresponding to dotted line Y-Y′ in the plan diagram shown in FIG. 10 and FIG. 11.

Here, in FIG. 3, a state is shown where the first insulation layer 200 surrounding the connection plug 300 is over-etched by etching when disposing the open portion 410 such that the upper portion of the connection plug 300 protrudes from the first insulation layer 200.

The open portion 410 is formed in the second insulation layer 400 by performing dry etching using photolithography.

In the present embodiment, as shown in FIG. 10 and FIG. 11, an open region 410′ exposed by the open portion 410 has a long shape comprising a second long direction a′ and a second width direction b′. For example, the shape of the open region 410′ may be a rectangular shape as shown in FIG. 10 or an oval shape as shown in FIG. 11. In the case of a rectangular shape, the long edge direction corresponds to the second length direction a′ and the short edge direction corresponds to the second width direction b′. In the case of an oval shape, the long axis direction corresponds to the second length direction a′ and the short axis direction corresponds to the second width direction b′. It will be noted that, in the present embodiment, the shape of the open region 410′ corresponds to the shape of the connection plug region 300′.

Additionally, the connection plug region 300′ and the open region 410′ are disposed such that the first length direction a and the second length direction a′ intersect so as to form a predetermined angle θ.

That is, during the etching to dispose the open portion 410, the open portion 410 is positioned such that the first length direction a of the connection plug region 300′ and the second length direction a′ of the open region 410′ intersect so as to form the predetermined angle θ.

To describe this in greater detail, the connection plug region 300′ and the open region 410′ are mutually disposed such that both edge portions 301 in the first length direction a of the connection plug region 300′ protrude from the open region 410′ and such that both edge portions 411 in the second length direction a′ of the open region 410′ protrude from the connection plug region 300′.

That is, in the cross section in the second length direction a′ of the open region 410′, as shown in FIG. 3, the open region 410′ is disposed so as to include the connection plug region 300′, and in the cross section in the second width direction b′ of the open region 410′, as shown in FIG. 4, the open region 410′ is disposed so as to fit inside the connection plug region 300′.

It will be noted that, in the present embodiment, the angle θ formed by the first length direction a and the second length direction a′ is 90 degrees.

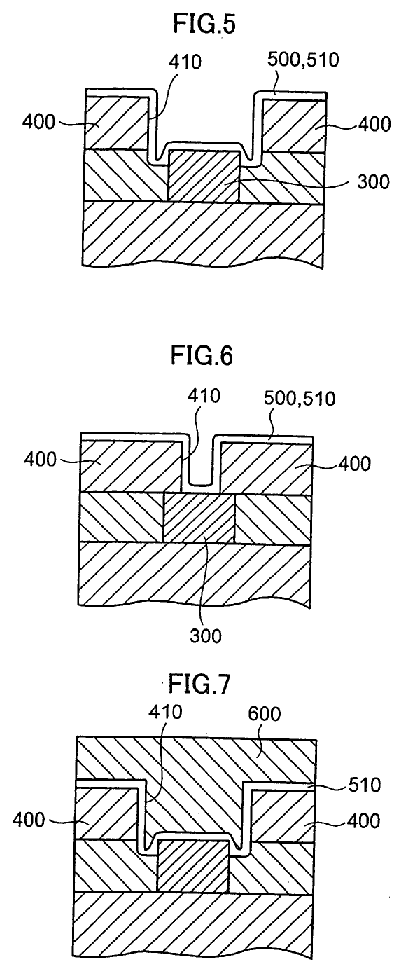

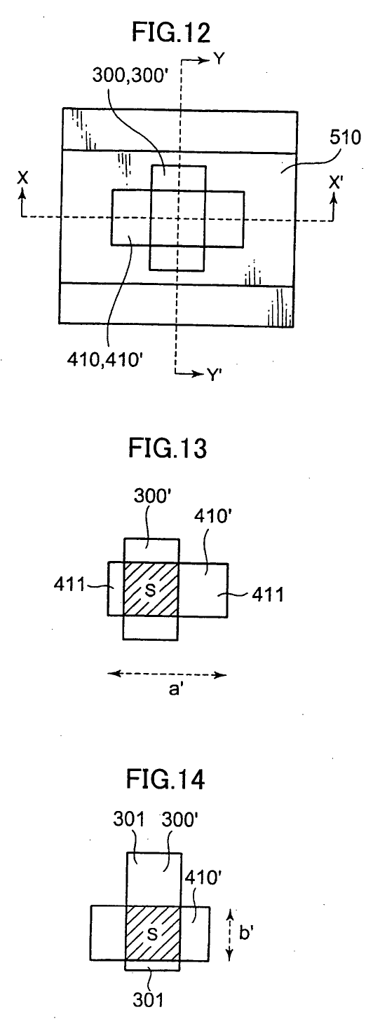

Next, as shown in FIG. 5, FIG. 6, and FIG. 12, a conductive film 500 is deposited on the second insulation layer 400 and inside the open portion 410, and the conductive film 500 is patterned to form on the second insulation layer 400 a wiring layer 510 electrically connected to the connection plug 300.

FIG. 5 is a cross-sectional diagram along dotted line X-X′ in the plan diagram shown in FIG. 12, and FIG. 6 is a cross-sectional diagram along dotted line Y-Y′ in the plan diagram shown in FIG. 12.

In the present embodiment, the material of the conductive film 500 is titanium nitride (TiN) or titanium aluminum nitride (TiAlN) and is deposited by sputtering. The conductive film 500 is formed with a certain film thickness on the second insulation layer 400 and on the inner surface of the open portion 410. That is, the conductive film 500 is formed in a state where part of the conductive film 500 sinks inside the open portion 410.

The wiring layer 510 formed by patterning the conductive film 500 is disposed so as to cover the connection plug region 300′ and the open region 410′.

Next, as shown in FIG. 7, a third insulation layer 600 is formed on the second insulation layer 400 and inside the open portion 410 so as to cover the wiring layer 510.

The third insulation layer 600 is configured by a silicon dioxide film (SiO₂) and is formed by CVD, for example. Here, the third insulation layer 600 is formed so as to fill the inside of the open portion 410.

In this manner, in the present invention, during the etching to dispose the open portion 410 in the second insulation layer 400, the open portion 410 is positioned such that the first length direction a of the connection plug region 300′ and the second length direction a′ of the open region 410′ form the predetermined angle θ and intersect, whereby the reliability of the electrical connection between the connection plug 300 and the conductive film 500 deposited inside the open portion 410 in the second insulation layer 400 is improved.

That is, according to this configuration, with respect to the second width direction b′ of the open region 410′, the inside surface of the open portion 410 and the upper surface of the connection plug 300 are continuous as shown in FIG. 6, so that it becomes possible to continuously deposit the conductive film 500 on the inner surface of the open portion 410 at this place. That is, even if the first insulation layer 200 surrounding the connection plug 300 is over-etched by etching to dispose the open portion 410 such that the upper portion of the connection plug 300 protrudes from the first insulation layer 200 and an open defect as indicated by the dotted line circle in FIG. 26 occurs in part of the conductive film 500 deposited on the inner surface of the open portion 410 such as in the second length direction a′ of the open region 410′, for example, it becomes possible to continuously deposit the conductive film 500 in the second width direction b′ of the open region 410′, so that it becomes possible to maintain the electrical connection between the connection plug 300 and the conductive film 500. That is, it becomes possible to improve the reliability of the electrical connection between the connection plug 300 and the conductive film 500.

Particularly when the conductive film 500 is deposited by sputtering, step coatability in sputtering is not good in comparison to chemical vapor deposition (CVD), for example, so that by applying the present invention, it becomes possible to provide more remarkable effects.

Moreover, according to this configuration, even when a shift occurs in positioning when disposing the connection plug 300 or the open portion 410, it becomes possible to maintain the area of contact between the connection plug 300 and the conductive film 500 deposited inside the open portion 410, and it becomes possible to improve the reliability of the electrical connection between the connection plug 300 and the conductive film 500.

That is, when a positional shift occurs in the second length direction a′ of the open region 410′ as shown in the plan diagram of FIG. 13, for example, both edge portions 411 protruding from the connection plug region 300′ in the second length direction a′ of the open portion 410′ act as positioning leeway, whereby it becomes possible to maintain an area S exposed by the open portion 410 in the connection plug region 300′. Moreover, when a positional shift occurs in the second width direction b′ of the open region 410′ as shown in the plan diagram of FIG. 14, both edge portions 301 protruding from the open region 410′ in the first length direction a of the connection plug region 300′ act as positioning leeway, whereby it becomes possible to maintain the area S exposed by the open portion 410 in the connection plug region 300′. Thus, it becomes possible to maintain the area of contact between the conductive film 500 deposited inside the open portion 410 and the connection plug 300, and it becomes possible to improve the reliability of the electrical connection between the connection plug 300 and the conductive film 500.

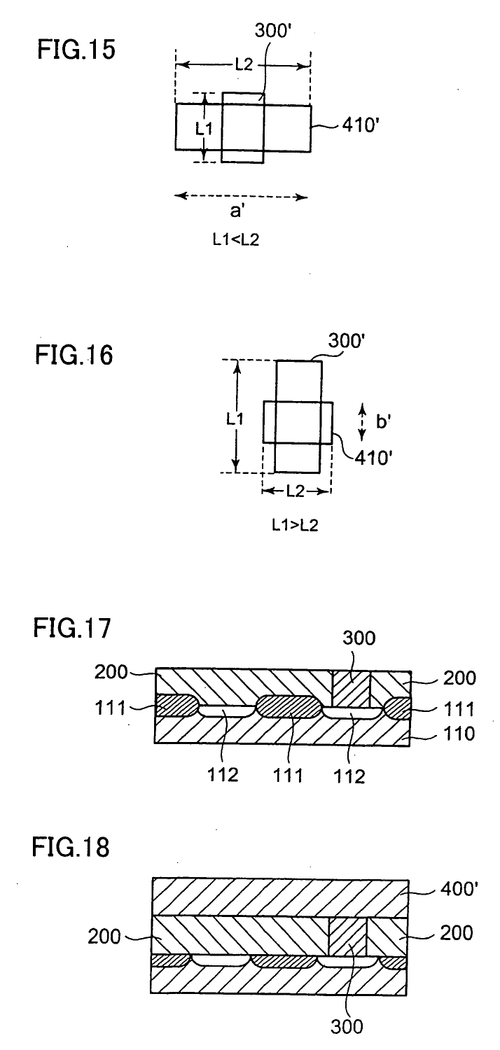

Here, in the present embodiment, when it can be supposed beforehand that a positional shift in the second length direction a′ of the open region 410′ will be greater than a positional shift in the second width direction b′ of the open region 410′, a length L1 of the connection plug region 300′ is set to be shorter than a length L2 of the open region 410′ as shown in FIG. 15. Moreover, when it can be supposed beforehand that a positional shift in the second width direction b′ of the open region 410′ will be greater than a positional shift in the second length direction a′ of the open region 410′, the length L2 of the open region 410′ is set to be shorter than the length L1 of the connection plug region 300′ as shown in FIG. 16. That is, by setting the length L1 of the connection plug region 300′ and the length L2 of the open region 410′ at different lengths on the basis of the expected positional shift direction, it becomes possible to reduce the superfluous region that does not contribute to the positional shift of the connection plug region 300′ or the open region 410′, and it becomes possible to make the area smaller.

### Second Exemplary Embodiment

Next, a semiconductor device manufacturing method pertaining to a second exemplary embodiment of the present invention will be described.

The second exemplary embodiment is one where the invention of the first exemplary embodiment is applied to a connection structure between a connection plug and a wiring layer electrically connected to an upper electrode of a capacitor where a lower electrode and an upper electrode are laminated via a ferroelectric film.

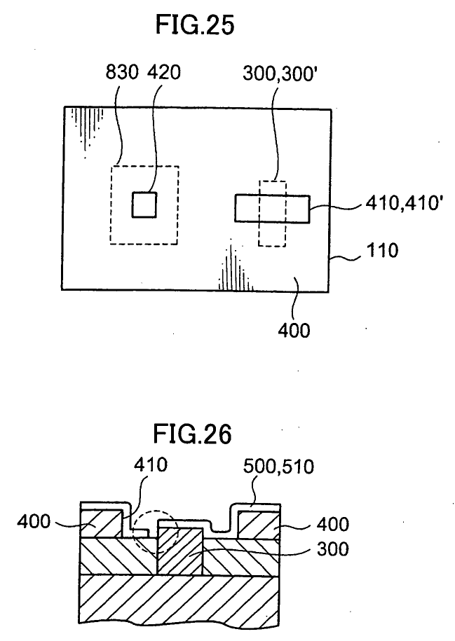

FIGS. 17 to 25 are step diagrams describing, in step order, the semiconductor device manufacturing method pertaining to the second exemplary embodiment of the invention. FIGS. 17 to 24 are cross-sectional diagrams, and FIG. 25 is a plan diagram.

In the semiconductor device manufacturing method pertaining to the second exemplary embodiment of the invention, first, as shown in FIG. 17, a conductive connection plug 300 is formed in a first insulation layer 200 formed on a semiconductor substrate 110. The conductive connection plug 300 penetrates the first insulation layer 200 and is electrically connected to the surface of the semiconductor substrate 110.

The semiconductor substrate 110 is a substrate whose material is silicon (Si), for example, and is disposed with plural impurity diffusion layers 112 separated by element dividing regions 111. The connection plug 300 is electrically connected to one of the impurity diffusion layers 112.

Next, as shown in FIG. 18, a second insulation layer 400′ is formed on the first insulation layer 200 so as to cover the connection plug 300.

The second insulation layer 400′ is configured by a silicon dioxide film (SiO₂) and is formed by CVD, for example.

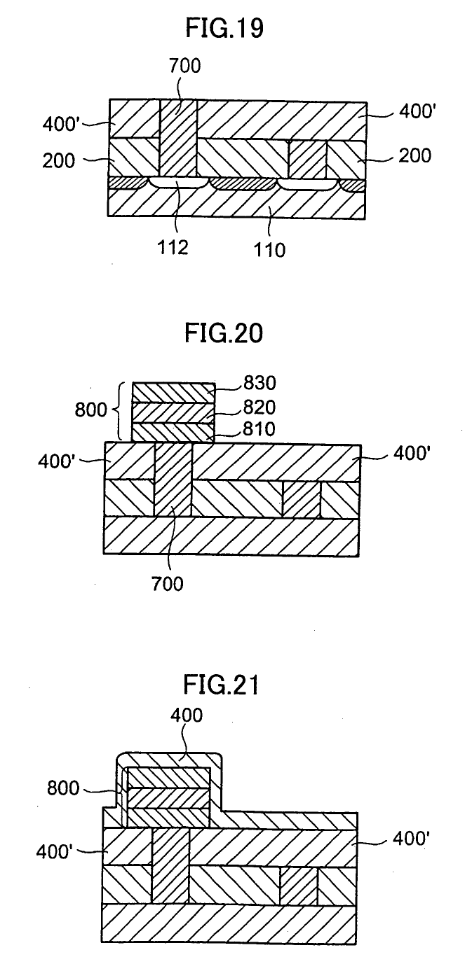

Next, as shown in FIG. 19, a capacitor-use connection plug 700 that penetrates the first insulation layer 200 and the second insulation layer 400′ is formed in the first insulation layer 200 and the second insulation layer 400′.

The capacitor-use connection plug 700 is electrically connected to one of the impurity diffusion layers 112 formed on the surface of the semiconductor substrate 110.

The capacitor-use connection plug 700 is formed by forming a contact hole in the first insulation layer 200 and the second insulation layer 400′ by etching using photolithography, then sequentially depositing, by sputtering or CVD, a metal layer whose material is titanium (Ti), titanium nitride (TiN), and tungsten (W) inside the contact hole and on the second insulation layer 400′, and then polishing the deposited metal layer by chemical mechanical polishing (CMP) or the like.

Next, as shown in FIG. 20, a capacitor 800 where a lower electrode 810, a ferroelectric film 820, and an upper electrode 830 are sequentially laminated is formed on the second insulation layer 400′.

The lower electrode 810 uses as its material a noble metal such as iridium (Ir) or iridium dioxide (IrO₂), for example, and is formed on the second insulation layer 400′ by sputtering so as to cover the capacitor-use connection plug 700.

The ferroelectric film 820 uses as its material a metal oxide dielectric and is formed on the lower electrode 810 by sputtering, spin coating, or metal-organic chemical vapor deposition (MO-CVD).

The upper electrode 830 uses as its material a noble metal such as platinum (Pt) or iridium (Ir) and is formed on the ferroelectric film 820 by sputtering.

Moreover, the capacitor 800 is formed by etching the sequentially laminated lower electrode 810, ferroelectric film 820, and upper electrode 830.

Next, as shown in FIG. 21, a second insulation film 400 is formed on the second insulation layer 400′ so as to cover the capacitor 800.

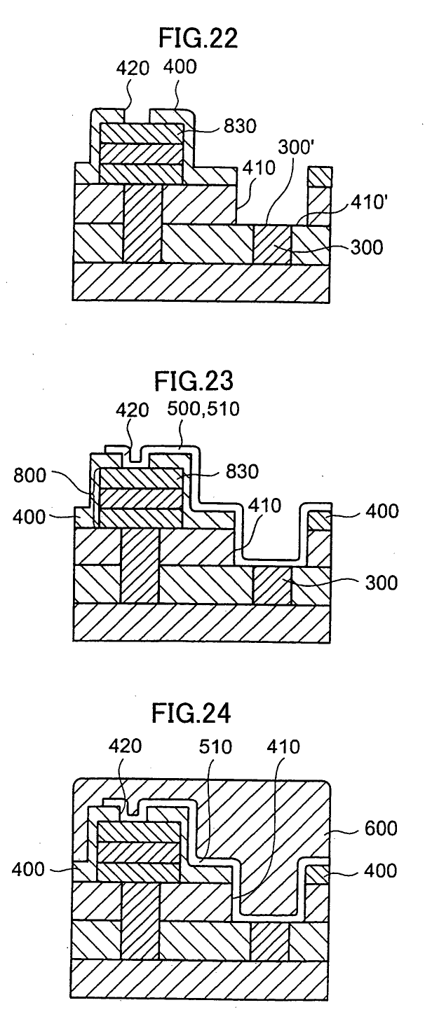

Moreover, as shown in FIG. 22, a capacitor-use open portion 420 that exposes part of the surface of the upper electrode 830 and an open portion 410 that exposes a connection plug region 300′ where the connection plug 300 is disposed are disposed in the second insulation film 400 by etching.

The open portion 410 and the open portion 420 are formed in the second insulation film 400 by performing dry etching using photolithography.

Here, the connection plug region 300′ and an open region 410′ exposed by the open portion 410 have the same shape and dispositional relationship as in the first exemplary embodiment. It will be noted that FIG. 25 is a plan diagram showing an example of this step.

Next, as shown in FIG. 23, a conductive film 500 is deposited all at once on the second insulation film 400, inside the open portion 410, and inside the capacitor-use open portion 420, and the conductive film 500 is patterned, whereby a wiring layer 510 that electrically connects the connection plug 300 and the upper electrode 830 of the capacitor 800 is formed on the second insulation film 400.

In the present embodiment, the material of the conductive film 500 is titanium nitride (TiN) or titanium aluminum nitride (TiAlN) and is deposited by sputtering.

Next, as shown in FIG. 24, a third insulation layer 600 is formed on the second insulation film 400 and inside the open portion 410 and the capacitor-use open portion 420 so as to cover the wiring layer 510.

In this manner, in the semiconductor device manufacturing method of the present embodiment, the connection structure between the connection plug 300 and the wiring layer 510 of the first exemplary embodiment is applied to a connection structure between the connection plug 300 and the wiring layer 510 electrically connected to the upper electrode 830 of the capacitor 800 where the lower electrode 810 and the upper electrode 830 are laminated via the ferroelectric film 820, whereby it becomes possible to more remarkably obtain the effects of the invention.

That is, when an attempt is made to deposit a conductive film by CVD when an attempt has been made to deposit the conductive film 500 inside the capacitor-use open portion 420 that exposes the surface of the upper electrode 830 of the capacitor 800, there is the potential for a reducing atmosphere to occur, and thus there is the potential for the electrical characteristics of the capacitor 800 to deteriorate. For this reason, it is preferable to deposit the conductive film 500 using sputtering. However, as described in the first exemplary embodiment, because step coatability in sputtering is not good in comparison to CVD, there has been the potential for the reliability of the electrical connection to not be sufficiently obtained when a conventional structure is used for the connection structure between the connection plug 300 and the conductive film 500. In the present invention, it becomes possible to maintain the reliability of the electrical connection between the connection plug 300 and the conductive film 500 even when the conductive film 500 is deposited by sputtering. That is, in the present invention, it becomes possible to improve the reliability of the electrical connection between the connection plug 300 and the conductive film 500 while maintaining the electrical characteristics of the capacitor 800.

What is claimed is:

1. A semiconductor device manufacturing method comprising:
forming, in a first insulation layer formed on a foundation layer, a conductive connection plug whose surface is exposed from the first insulation layer and which penetrates the first insulation layer and is electrically connected to the foundation layer;
forming a second insulation layer on the surface of the connection plug and on the first insulation layer;
etching to dispose in the second insulation layer an open portion that exposes the connection plug and the first insulation layer;
depositing a conductive film on the second insulation layer and inside the open portion; and
patterning the deposited conductive film to form on the second insulation layer a wiring layer electrically connected to the connection plug,
wherein
a connection plug region that is the surface of the connection plug has a long shape comprising a first length direction and a first width direction,
an open region that is exposed by the open portion has a long shape comprising a second length direction and a second width direction, and
during the etching, the open portion is positioned such that the first length direction of the connection plug region and the second length direction of the open region intersect so as to form a predetermined angle.

2. The semiconductor device manufacturing method of claim 1, wherein the connection plug region and the open region are mutually disposed such that both edge portions in the first length direction of the connection plug region protrude from the open region and such that both edge portions in the second length direction of the open region protrude from the connection plug region.

3. The semiconductor device manufacturing method of claim 1, wherein the shapes of the connection plug region and the open region are rectangular.

4. The semiconductor device manufacturing method of claim 1, wherein the shapes of the connection plug region and the open region are oval.

5. The semiconductor device manufacturing method of claim 1, wherein the angle formed by the first length direction and the second length direction is 90 degrees.

6. The semiconductor device manufacturing method of claim 1, wherein the conductive film deposited on the second insulation layer and inside the open portion is deposited by sputtering.

7. The semiconductor device manufacturing method of claim 1, wherein the material of the conductive film is titanium nitride.

8. The semiconductor device manufacturing method of claim 1, wherein the material of the conductive film is titanium aluminum nitride.

9. The semiconductor device manufacturing method of claim 1, further comprising forming a third insulation layer on the second insulation layer and inside the open portion so as to cover the wiring layer.

10. The semiconductor device manufacturing method of claim 1, wherein the length in the first length direction of the connection plug region and the length in the second length direction of the open region are different.

11. The semiconductor device manufacturing method of claim 1, wherein
the wiring layer is a wiring layer electrically connected to an upper electrode of a capacitor that is formed by laminating a lower electrode and the upper electrode via a ferroelectric film,
the second insulation layer covers the capacitor so as to expose part of the surface of the upper electrode, and
the conductive film is deposited on the exposed surface of the upper electrode of the capacitor.

12. The semiconductor device manufacturing method of claim 1, wherein during the etching, the first insulation layer is over-etched such that part of the connection plug protrudes from the first insulation layer.

13. A semiconductor device manufacturing method comprising:
forming, on a semiconductor substrate including a surface disposed with an impurity diffusion layer, a capacitor that is formed by laminating a lower electrode and an upper electrode via a ferroelectric film and a connection plug that is electrically connected to the impurity diffusion layer;
forming an insulation layer on the semiconductor substrate so as to cover the capacitor and a connection plug region where the connection plug is disposed;
etching so as to dispose in the insulation layer an open portion that exposes the connection plug region and a capacitor-use open portion that exposes part of the surface of the upper electrode of the capacitor;
depositing a conductive film on the insulation layer, inside the open portion, and inside the capacitor-use open portion; and
patterning the deposited conductive film to form on the second insulation layer a wiring layer that electrically connects the connection plug and the upper electrode of the capacitor,
wherein
the connection plug region has a long shape comprising a first length direction and a first width direction,
an open region that is exposed by the open portion has a long shape comprising a second length direction and a second width direction, and
during the etching, the open portion is positioned such that the first length direction of the connection plug region and the second length direction of the open region intersect so as to form a predetermined angle.

14. The semiconductor device manufacturing method of claim 13, wherein the connection plug region and the open region are mutually disposed such that both edge portions in the first length direction of the connection plug region protrude from the open region and such that both edge portions in the second length direction of the open region protrude from the connection plug region.

15. The semiconductor device manufacturing method of claim 13, wherein the shapes of the connection plug region and the open region are rectangular.

16. The semiconductor device manufacturing method of claim 13, wherein the shapes of the connection plug region and the open region are oval.

17. The semiconductor device manufacturing method of claim 13, wherein the angle formed by the first length direction and the second length direction is 90 degrees.

18. The semiconductor device manufacturing method of claim 13, wherein the conductive film deposited on the second insulation layer, inside the open portion, and inside the capacitor-use open portion is deposited by sputtering.

19. The semiconductor device manufacturing method of claim 13, wherein the material of the conductive film is titanium nitride.

20. The semiconductor device manufacturing method of claim 13, wherein the material of the conductive film is titanium aluminum nitride.

21. The semiconductor device manufacturing method of claim 13, wherein the length in the first length direction of the connection plug region and the length in the second length direction of the open region are different.
